(19) United States
(12) Patent Application Publication
(10) Pub. No.: US 2010/0271550 A1
(43) Pub. Date: Oct. 28, 2010

(54) CRT TO LCD CONVERSION

(75) Inventors: Donald J. Jardee, Chesterland, OH (US); Jeffery C. Williams, Eastlake, OH (US)

Correspondence Address: Husch Blackwell Sanders, LLP;Husch Blackwell Sanders LLP Welsh & Katz, 120 S RIVERSIDE PLAZA, 22ND FLOOR, CHICAGO, IL, 60606, US

(73) Assignee: HEICO Corporation, Hollywood, FL (US)

(21) Appl. No.: 12/445,654

(22) PCT Filed: Oct. 16, 2007
(86) PCT No.: PCT/US07/22020

§ 371 Date: Jul. 13, 2010

Related U.S. Application Data
(60) Provisional application No. 60/852,047, filed on Oct. 16, 2006.

(51) Int. Cl. G06F 13/14; H03M 1/12

(52) U.S. Cl. 348/572; 345/520; 348/E07.003

(57) ABSTRACT

A method and apparatus are provided for providing a cockpit display in an aircraft. The method includes the steps of receiving a plurality of independent signals formatted for generating a cockpit image on a cathode ray tube of the aircraft, converting the received plurality of analog signals into an equivalent low voltage digital signal and displaying the cockpit image on a flat panel display of the aircraft using the equivalent low voltage digital signal.

### FIELD OF THE INVENTION

The field of the invention relates to aircraft and more particularly to the control displays present in the cockpit of an aircraft.

### BACKGROUND OF THE INVENTION

Electronic Flight Instrument Systems (EFIS) utilized a Cathode Ray Tube (CRT) to display information to the pilot are well known. The use of CRTs began in the early 1980's and continued until the early 2000's. In this time frame CRT's were the best technology available, replacing the mechanical Attitude Direction Indicator (ADD, the Horizontal Situation Indicator (HSI)/Navigation Situation Display, the Engine Indicating, Crew Alert System (EICAS) and other cockpit instruments. These CRT units were in general very reliable compared to the mechanical instruments they replaced.

CRTs have been used for information displays since the 1940's with monochrome and later with color CRTs. CRTs dominated all segments of the display market. Liquid Crystal Displays (LCD) began commercial success in the early 1990's, however; at that time LCDs in general were of poor quality. During the 1990's the quality issues were resolved making LCDs more and more popular. With the increase in screen resolution, consumer acceptance of LCDs made them the display of choice. Today other technologies—including plasma screens and organic light emitting diodes (OLED) have joined LCDs in commercial success, under the general classification of Flat Panel Displays (FPDs). Manufacturers started reducing production of CRTs in the late 1990's, as the efficiency of LCD production increased thus reducing unit costs. The production of LCDs exceeded the production of CRTs in 2003. Since then the production of CRTs has dramatically declined making repair of CRT based units more and more difficult if not impossible, thus repairs are far more costly due to the declining production of CRTs.

Today, FPDs have replaced CRTs in the industrial and consumer market because of dramatic reliability and quality improvements. In the aviation industry, new production units are almost all FPD technology—from the smallest general aviation airplanes to the largest airliners. Because of the shift away from CRT technology production to FPD production in the commercial marketplace, the cost for replacement CRTs have risen dramatically, or the parts are no longer procurable. This is forcing aerospace OEMs to discontinue support for their CRT display units. However, most aircraft utilizing CRT technology are “young” or “midlife” aircraft, and have many years of service life remaining.

The CRT-based Display Units, with the exception of the CRT itself and the High Voltage Power Supply (HVPS), are rugged electronics of the digital age and thusly robust and reliable. The CRTs and HVPS are the high failure items, requiring frequent maintenance and calibration to keep performance within functional limits. This makes replacing the CRT with an FPD “module” a perfect fit to continue operating the same display units without expensive aircraft modifications.

### BRIEF DESCRIPTION OF THE DRAWINGS

FIG. 1 depicts a prior instrument display for an aircraft;

FIG. 2 depicts an instrument display under an illustrated embodiment of the invention;

FIG. 3 depicts a signal conversion system of FIG. 2;

FIG. 4 depicts an instrument display under an alternative illustrated embodiment of the invention;

FIG. 5 depicts a signal conversion system of FIG. 4;

FIG. 6 depicts a prior art display for an in flight entertainment system for an aircraft; and

FIG. 7depicts an entertainment display of an aircraft under an illustrated embodiment of the invention.

### SUMMARY

A method and apparatus are provided for providing a cockpit display in an aircraft. The method includes the steps of receiving a plurality of independent signals formatted for generating a cockpit image on a cathode ray tube of the aircraft, converting the received plurality of analog signals into an equivalent low voltage digital signal and

displaying the cockpit image on a flat panel display of the aircraft using the equivalent low voltage digital signal.

### DETAILED DESCRIPTION OF AN ILLUSTRATED EMBODIMENT

In general, CRTs in aircraft are obsolescent. In fact, display Unit manufacturers have stated they will stop all support of CRTs within 2-5 years. As a consequence, it is predicted that the cost of CRTs will increasing dramatically.

CRTs have relatively limited reliability and “Refurbished” or “Repaired” CRTs have very low reliability. In addition, the High Voltage Power Supply that supplies power to a CRT also has a low reliability. Further, frequent calibration and adjustments are needed, requiring removal and reinstallation.

There is a relatively large number of aircraft in service with CRTs. Transport aircraft have more than 34,000 CRT display units in service. Regional and business jets have more than 6,000 CRT display units in service.

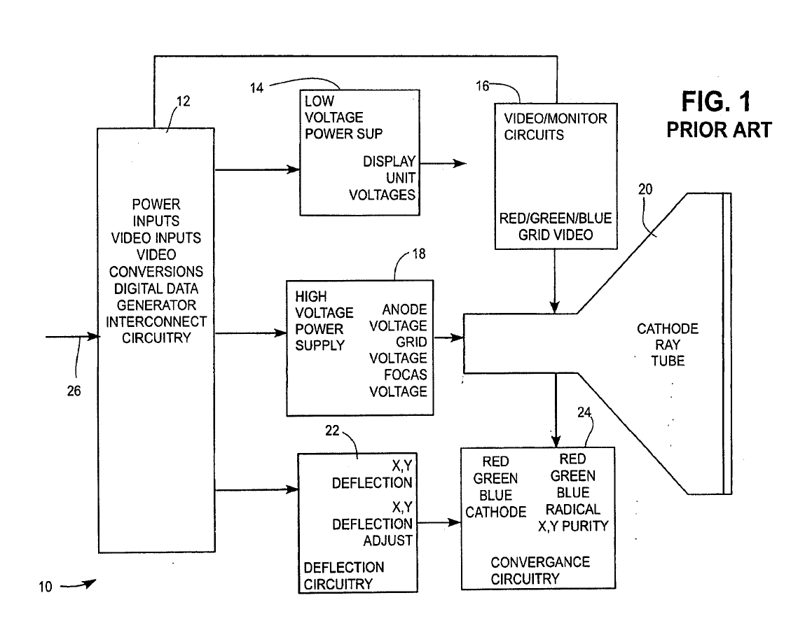

FIG. 1 depicts a conventional CRT display system 10 used within an aircraft. The CRT display system 10 may be used to display the Attitude Direction Indicator (ADI), the Horizontal Situation Indicator (HSI)/Navigation Situation Display, the Engine Indicating, Crew Alert System (EICAS) and other cockpit instruments. Cockpit instruments are typically displayed in predetermined locations on the CRT 20 of the CRT display system 10.

In such conventional systems 10, a digital signal is received from a data bus 26 of the aircraft. The digital signal received from the bus 26 is typically packet based. The instrument readings displayed on the various instruments located on the display of the CRT 20 are typically provided by a separate symbol generator of the aircraft that is in turn connected to the bus 26. The graphics used to provide a context for the instrument readings may be provided by the symbol generator or may be generated locally by a processor located within the input board 12. In general, the input board 12 may host a number of independent processes equal to the number of instruments shown on the CRT 20, where each independent process receives instrument data from the symbol generator at a separate system address.

The input board 12 receives the instrument readings from the symbol generator and formats the data for display on the CRT 20. In order to display the instruments, the input board 12 may provide display voltages through a low voltage power supply 14 and a high voltage power supply 18.

The high voltage power supply may provide a set of grid voltages formatted for the particular CRT 20 used within the system 10. In the case of a color CRT 20, the high voltage power supply may apply approximately 25 kV to the anode (G4) of the CRT 20 and 4-8 kV to the G3 focus grid of the CRT 20.

The input board 12 may also apply a set of G2 grid voltages to the CRT 20 through a grid control 16. In the case of a color CRT 20, the G2 grid voltages may be on the order of several hundred volts and may be separately adjusted among the red/green/blue electron beams to ensure sufficient brightness levels.

The input board 12 may also generate a raster via deflection circuitry 22 and modulate that raster via the deflection circuitry 22 and convergence circuitry 24. In the case of a color monitor, the input board 12 may generate a separate modulation signal for the red, green and blue electron beams that is applied to the respective red, green and blue cathodes of the CRT 20. The input board may also superimpose synchronization information onto the green modulation signal that is extracted within the deflection circuitry 22 and applied to the X and Y deflection yokes.

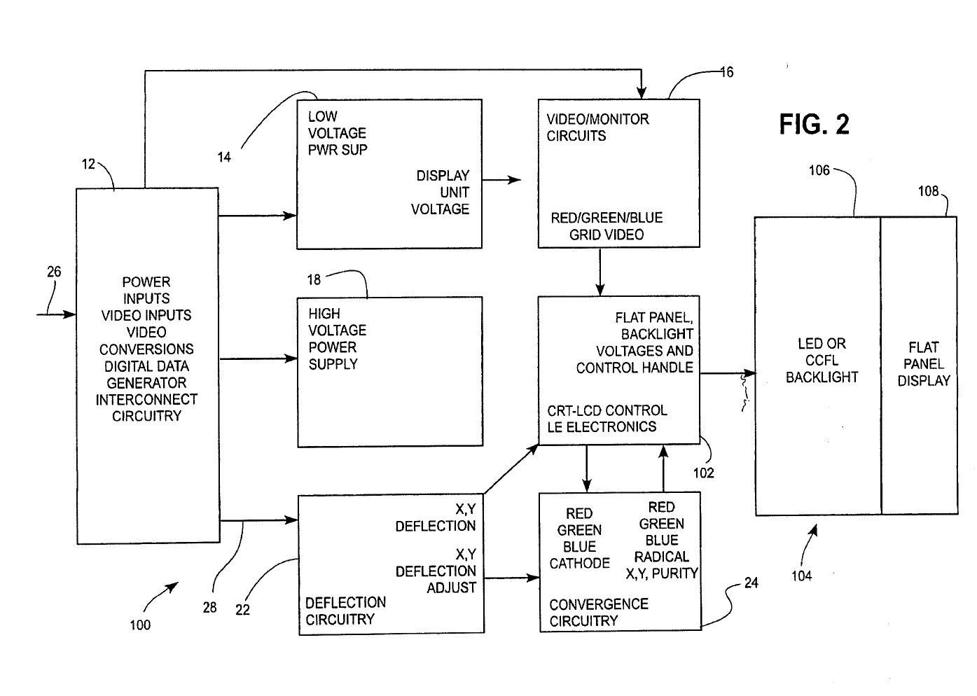

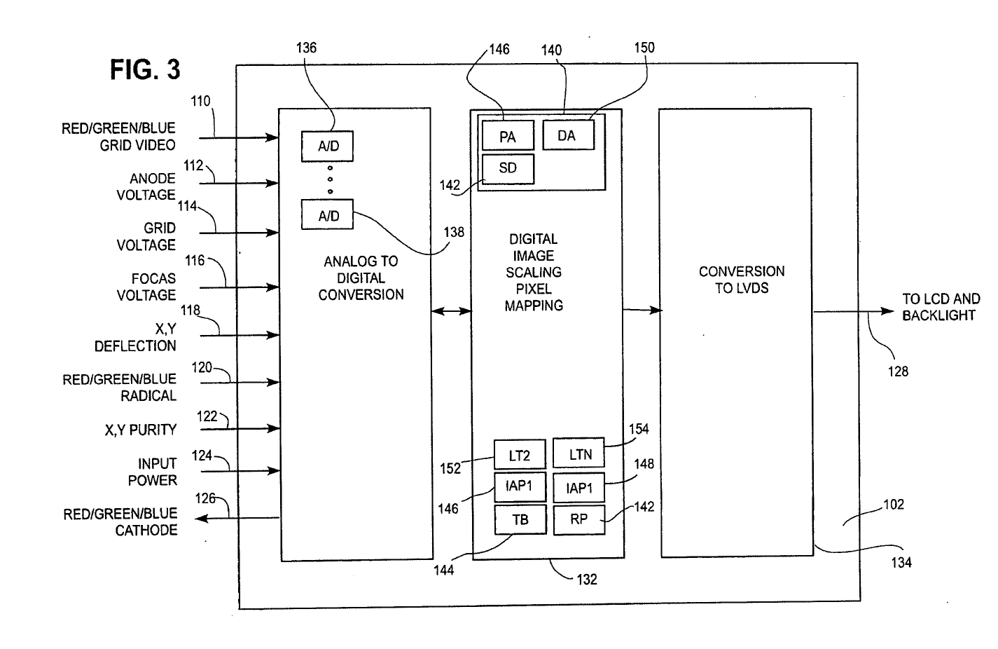

FIG. 2 depicts a display system 100 under an illustrated embodiment of the invention. Under illustrated embodiments, at least some elements 12, 14, 16, 18, 22, 24 of the prior display system 10 are reused in this display system 100. The existing CRT 20 is replaced with a FPD w/backlight 104 for maximum reliability. In this regard, the LCD w/LED backlight 104 has a reliability of greater than 18,000 hours.

The High Voltage Power Supply 18 can be removed (or left in place as shown in FIG. 2), further improving reliability. The replacement FPD 104 utilizes an industry standard LVDS interface dramatically reducing future obsolescence issues. The weight savings of the system 100 is approx 5 lbs per unit.

The system 100 provides low initial costs. In fact, the per unit cost is similar to current CRT unit repair costs when CRT is replaced. The use of the system 100 would incur no aircraft modification costs since connections can be made using existing connectors.

In general, currently repairs and refurbishments are available for CRTs 20. These repairs/refurbishments have demonstrated reliability of approximately 6,000 aircraft flight hours, leading to excessive unscheduled removals for CRT-based units.

The potential obsolescence issues with FPDs used in the CRT replacement have been addressed by using a standard low voltage digital signaling (LVDS) video interface between the FPD and the display unit. Should an FPD become obsolete it can be replaced with another FPD utilizing standard video format.

With the IAS-proposed design, no aircraft modifications are necessary. The FPD module replacement units are 100% compatible with existing CRT units in the aircraft. No aircraft downtime is necessary, the CRT to FPD replacement can be accomplished on an as-fail basis.

Technically, the FPD is a far superior display device. Primary advantages of an FPD over CRTs include a reduction in space and weight. The system 100 results in a 70% reduction in size and reduction in weight. There is no need for associated heavy shielding and mounting materials.

There is also a power consumption reduction. The electronics drive is now modem digital very large scale integration electronics vs analog tubes and transistors.

There is also a reduction in heat generation. In this regard, analog drive electronics eliminated. No high voltage power supply.

As mentioned above, the reliability of the system 10 is increased significantly by about double the best CRT 20. There are no high voltage power supply failures. There are also no cathode drive to fail and no electron gun deflection amplifiers to fail.

Safety is also improved. FPDs 104 do not contain a vacuum therefore eliminating implosion hazard. No high voltage is present thereby eliminating arcing hazards. The FPD 104 is rugged. The FPD 104 is not affected by magnetic fields or electromagnetic interference therefore shielding is eliminated.

Convergence yokes are eliminated, thereby contributing to the space requirements. Deflection circuits eliminated as well as high voltage power supplies resulting in a similar conservation of space.

The FPD 104 reduces maintenance requirements. The individual subcomponents easily replaced, such as the LCD module, the backlight module and the interface electronics module.

The FPD 104 does not require adjustments. No adjustments/calibrations needed reducing removals and maintenance. Convergence adjustments are eliminated. Similarly, focus adjustments, deflection and purity adjustments eliminated.

Human Factors are also eliminated. The FPD 104 provides superior sunlight readability under moderate and high ambient light conditions. The FPD 104 provides an increase in image quality—easier to see symbology on FPD 104.

Turning now to the system 100, a discussion will be offered as to the structure and functionality of the system 100. In general, there are numerous technologies used to display images on CRT video display devices. The manufacturer of the CRT 20, the application of the video display unit by aircraft function, and the environment in which the display unit operates within the aircraft are accommodated by the embodiment described in conjunction with system 100. Although CRT units vary in design details, all have somewhat similar electronics to drive the CRT (e.g., see Typical CRT display unit FIG. 1). There are three approaches that can be used to replace a CRT with a FPD in virually any display unit. The actual method used will vary dependent on the technology of the unit and customer requirements. In general, three different approaches will be described, as follows: 1) receive signals intended for the CRT and convert them to a format suitable for use in an FPD, 2) receive digital signals from the display unit data bus of the aircraft and convert directly to digital data for use on a FPD, and 3) receive a set of raw video input signals and electronically process these signals into a format suitable for FPD.

In the first example (FIG. 2) only the CRT is removed and replaced with an FPD. The CRT control electronics substantially remain intact except the high voltage power supply, which may be capped to prevent high voltage from arcing within the unit. The CRT-LCD control interface electronics is added to take the CRT control signals and translate to the appropriate digital data control signals for use with a backlit flat panel display.

As shown, FIG. 2, the CRT 20 is removed and replaced with a signal processing system 102. The signal processing system 102 may receive a plurality of analog signals intended for the CRT 20 and convert the analog signals into a low voltage digital signaling (LVDS) video signal for application to the FPD 104. The FPD 104 may include an imaging section 106 coupled to an actual flat panel display 108. The imaging section 106 may be based upon a light emitting diode (LED) technology or a liquid crystal display (LCD) technology with cold cathode fluorescent lamp (CCFL) back lighting.

The imaging section may receive a number of analog signals 110, 112, 114, 116, 118, 120, 122, 124, 126 from the analog control circuitry 12, 16, 22, 24 of the aircraft and generate a LVDS video signal 128 that corresponds to the combined imaging content of the analog signals 110, 112, 114, 116, 118, 120, 122, 124, 126. The generation of the LVDS video signal 128 may occur based upon a number of different parallel and sequential processes occurring within the analog to digital (A/D) converter 130, the digital image scaling, pixel mapping processing (mapping) section 132 and the conversion to LVDS processing section 134.

As a first step, the A/D converter 130 may sample the incoming analog signals 110, 112, 114, 116, 118, 120, 122, 124, 126 under control of a time base 144 and transfer the samples to the mapping section 132. Within the mapping section 132, the samples may be initially saved in a sampled data portion 142 of a memory 140.

Once the data has been saved to the sampled data portion 142, a raster processor 142 may begin monitoring the sampled data from the x, y deflection signal 118 for frame synchronization events and vertical retrace events. The raster processor 142 may also monitor for horizontal retrace events.

Upon detecting a frame synchronization event, the raster processor 142 may begin mapping red, blue and green data samples from the r/g/b cathode signal 126 into corresponding locations of a preliminary image memory. In this regard, a first portion of the preliminary image memory 146 may correspond to a top row of pixels of the display 104, a second portion of the memory 146 may correspond to a second row of pixel in the display 104, etc. The number of portions within memory 146 may correspond to the vertical number of pixels in the display 104. Similarly, the number of memory locations within each portion may correspond to the number of horizontal pixels in the display. Further each memory location within a portion of memory 146 may actually have three memory location (i.e., one memory location for a red sample, one for a green sample and one for a blue sample.

Once the image data has been mapped into the preliminary image array 146, a number of image adjustment processors (IAP1 146-IAPN 148) may adjust the image by rewriting the data back into the array 146 or into a display image array 150. It may be noted in this regard, that the image adjustment processors 146, 148 may rely upon one or more lookup tables 152, 154 to perform the image adjustments. For example, for a given set of inputs 110, 112, 114, 116, 118, 120, 122, 124, 126, the CRT 20 has a set of characteristics that produces a predetermined pixel response on the CRT 20 based upon that set of inputs.

For example, the red, green and blue phosphors of the CRT 20 all operate a different levels of efficiency, with red being the lowest. Accordingly, the red drive signal on input 126 is scaled to lower the red drive to the FPD 104. In general, the red, green and blue samples within the preliminary sample data array 146 are all scaled by an image adjust processor 146, 148 to match the characteristics of the FPD 104.

Similarly, the image adjustment processors may also correct for the anomalies of the deflection characteristics of the CRT 20. For example, a second image adjustment processor 146, 148 may provide geometric CRT corrections. In this regard, the geometry of the CRT causes the electron flows to pixels at the margins of the screen of the CRT to be different than the center. The geometric characteristics are corrected by the second image adjust processor 146, 148.

Similarly, a third image adjustment processor 146, 148 may provide pin cushion correction. In this regard, when the location of the image is varied in the vertical direction, the image is distorted. The pin cushion characteristics of the CRT 20 are corrected by the third image adjust processor 146, 148.

Similarly, a fourth image adjustment processor 146, 148 may provide linearity correction. In this regard, when the electron beam sweeps across the screen the electron flow is non-linear based upon the portion of the screen involved. The linearity characteristics of the CRT 20 are corrected by the fourth image adjust processor 146, 148.

Similarly, a fifth image adjustment processor 146, 148 may provide x and y deflection amplifier correction. In this regard, when the location of the image is varied in the vertical or horizontal direction, the rate of sweep is distorted. The x and y deflection characteristics of the CRT 20 are corrected by the fifth image adjust processor 146, 148.

Similarly, a sixth image adjustment processor 146, 148 may provide red, green and blue convergence correction. In this regard, when the electron beams from the red, blue and green cathodes of the CRT 20 must be focused on a set of corresponding phosphors. The red, green and blue convergence characteristics of the CRT 20 are corrected by the sixth image adjust processor 146, 148.

In addition, another image adjustment processor 146, 148 may provide gamma correction of the image. A still further image adjustment processor 146, 148 may control backlight brightness through a defocusing operation.

Finally, a still further image adjustment processor 146, 148 may eliminate orbiting. Orbiting is used in CRTs to prevent burn-in. In this case, the image adjustment processor 146, 148 detects and removes the vertical and horizontal offsets used with orbiting.

Once the image within the display image array 150 has been corrected, the image may be transferred to the converter 134. Within the converter 150, the corrected image is converted into the LVDS video format and displayed on the display 104.

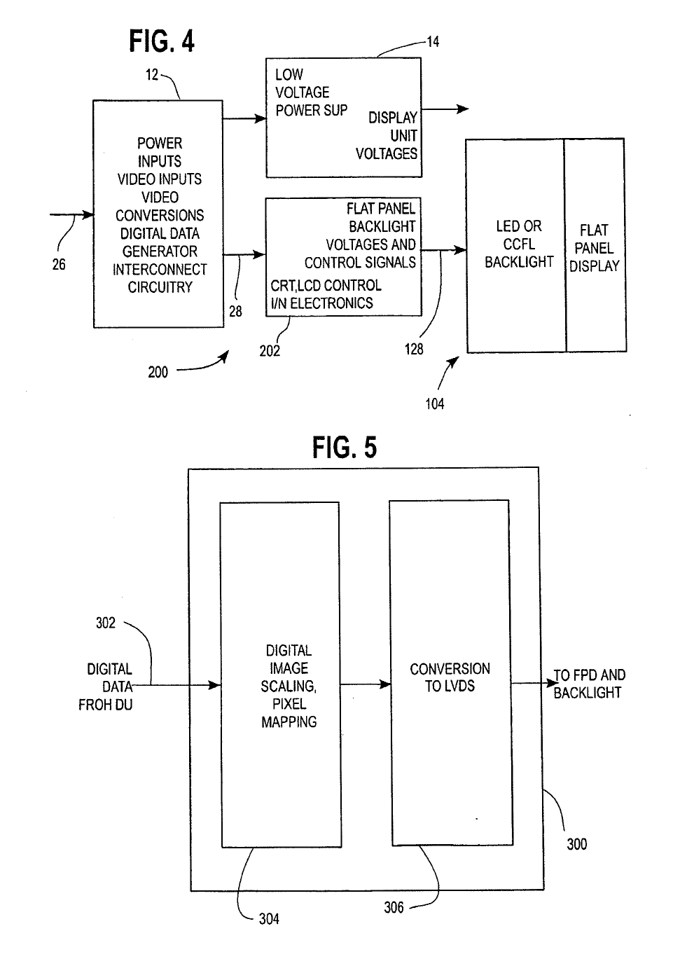

In the second example (FIG. 4) the x, y deflection circuitry 22, along with the high voltage power supply 18, is removed from the display unit of the aircraft. In the embodiment illustrated in FIG. 4, the display system 200 receives digital data directly from the display unit data bus 28. The low voltage power supply 14 is left intact to power the new display unit electronics.

In this configuration, the CRT-FPD control interface electronics 202 takes the digital data from the display unit digital data bus 202, applies scaling, pixel mapping then converts the generated digital data into a LVDS video signal. The LVDS video signal is provided at an output 128 to the FPD 104, as above.

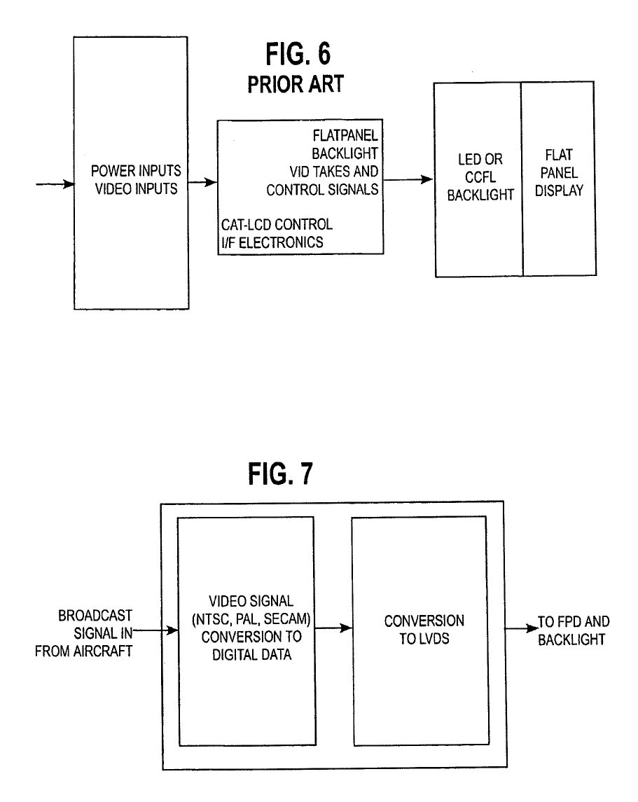

FIG. 7 provides another illustrated embodiment of the invention. In FIG. 7, the system 300 is used to replace CRT display units (FIG. 6) such as those used in In-Flight Entertainment CRT units. The CRT and electronics is generally all on one circuit board making it impractical to remove or disable portions of the electronics. Additionally due to the low cost of these display units it is not feasible to convert the existing signals to a FPD signal. The input to these display units is generally a standard broadcast video signal (e.g., NTSC, CCAM, PAL, etc.). The power supply is removed along with all the electronics and CRT. The power supply is replaced with a power supply specifically targeting the voltages needed by the control interface electronics. The control interface is then connected to the broadcast signal input connector and the power supply is connected to aircraft power.

A specific embodiment of an aircraft display has been described for the purpose of illustrating the manner in which the invention is made and used. It should be understood that the implementation of other variations and modifications of the invention and its various aspects will be apparent to one skilled in the art, and that the invention is not limited by the specific embodiments described. Therefore, it is contemplated to cover the present invention and any and all modifications, variations, or equivalents that fall within the true spirit and scope of the basic underlying principles disclosed and claimed herein.

1. A method of providing a cockpit display in an aircraft comprising:
receiving a plurality of independent signals formatted for generating a cockpit image on a cathode ray tube of the aircraft;
converting the received plurality of analog signals into an equivalent low voltage digital signal; and
displaying the cockpit image on a flat panel display of the aircraft using the equivalent low voltage digital signal.

2. The method of providing the display as in claim 1 wherein the independent signals further comprise a plurality of cathode signals received on a plurality of respective input connections.

3. The method of providing the display as in claim 2 wherein the plurality of cathode signals further comprises a green composite video signal.

4. The method of providing the display as in claim 3 wherein the green composite video signal further comprises a synchronization signal.

5. The method of providing the display as in claim 1 further comprising providing a plurality of memory locations for receiving a video frame and dividing the plurality of memory locations into a plurality of portions equal to a number of horizontal scan lines of the cathode ray tube.

6. The method of providing the display as in claim 5 further comprising associating each of the plurality of portions with a respective horizontal scan line of the analog video signal.

7. The method of providing the display as in claim 6 further comprising detecting a vertical synch signal within the analog signals and sequentially writing pixel information into each of the plurality of portions in a predetermined order.

8. The method of providing the display as in claim 7 further comprising detecting a horizontal synch signal and terminating entry of pixel information into a first portion of the plurality of portions and initiating entry of pixel information into a second portion of a plurality of portions.

9. The method of providing the display as in claim 8 further comprising providing a red, green and blue memory element for each of the plurality of memory locations.

10. The method of providing the display as in claim 7 wherein the step of detecting the vertical synch signal further comprises monitoring a vertical output signal formatted for a vertical coil and detecting the vertical signal when the monitored signal exceeds a predetermined threshold value.

11. The method of providing the display as in claim 7 wherein the step of detecting the horizontal synch signal further comprises monitoring a horizontal output signal formatted for a horizontal coil and detecting the vertical signal when the monitored signal exceeds a predetermined threshold value.

12. The method of providing the display as in claim 1 wherein the plurality of independent signals further comprise packetized data received through a computer network.

13. The method of providing the display as in claim 1 further comprising sampling the plurality of analog signals to obtain a digital signal.

14. The method of providing the display as in claim 13 further comprising scaling the sampled digital signals.

15. The method of providing the display as in claim 14 further comprising mapping the scaled digital signals into a memory.

16. The method of providing the display as in claim 15 further comprising correcting the digital signals.

17. The method of providing the display as in claim 16 wherein the step of correcting the digital signals further comprises correcting at least some portions of the mapped digital signal for geometric aberrations of the cathode ray tube.

18. The method of providing the display as in claim 16 wherein the step of correcting the digital signals further comprises correcting at least some portions of the mapped digital signal for pincushion aberrations of the cathode ray tube.

19. The method of providing the display as in claim 16 wherein the step of correcting the digital signals further comprises correcting at least some portions of the mapped digital signal for linearity aberrations of the cathode ray tube.

20. The method of providing the display as in claim 16 wherein the step of correcting the digital signals further comprises correcting at least some portions of the mapped digital signal for X and Y deflection amplifier aberrations of the cathode ray tube.

21. The method of providing the display as in claim 16 wherein the step of correcting the digital signals further comprises correcting at least some portions of the mapped digital signal for red, green and blue convergence aberrations of the cathode ray tube.

22. The method of providing the display as in claim 16 wherein the step of correcting the digital signals further comprises correcting at least some portions of the mapped digital signal for gamma illumination aberrations of the cathode ray tube.

23. The method of providing the display as in claim 16 wherein the step of correcting the digital signals further comprises correcting at least some portions of the mapped digital signal for red, green and blue cathode amplifier illumination aberrations of the cathode ray tube.

24. The method of providing the display as in claim 1 wherein the step of correcting the digital signals further comprises removing an offset that causes orbiting.

25. An apparatus for providing a cockpit display in an aircraft comprising:
means for receiving a plurality of independent signals formatted for generating a cockpit image on a cathode ray tube of the aircraft;
means for converting the received plurality of analog signals into an equivalent low voltage digital signal; and
means for displaying the cockpit image on a flat panel display of the aircraft using the equivalent low voltage digital signal.
